(19) United States
(12) Patent Application Publication
(10) Pub. No.: US 2009/0309217 A1
(43) Pub. Date: Dec. 17, 2009

(54) FLIP-CHIP INTERCONNECTION WITH A SMALL PASSIVATION LAYER OPENING

(75) Inventor: Wojtek Sudol, Andover, MA (US)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/306,397

(22) PCT Filed: Jun. 20, 2007
(86) PCT No.: PCT/IB07/52389

§ 371 Date: Dec. 23, 2008

(51) Int. Cl. H01L 23/498; H01L 21/78

(52) U.S. Cl. 257/737; 438/113; 257/778; 257/E23.07; 257/E21.599

(57) ABSTRACT

A flip-chip electrical coupling (100, 200, 300) is formed between first and second electrical components (110, 180; 410, 480). The coupling (100, 200, 300) includes a bump (240, 340) and a contact pad (315). The first electrical component (110, 210, 310, 410) includes the contact pad (315) electrically coupled to the first electrical component (110, 210, 310, 410) and a passivation layer (130, 230, 330) overlying the first electrical component (110, 210, 310, 410) and the contact pad (315). The passivation layer (130, 230, 330) is arranged having an opening (120, 220, 320) positioned over the contact pad (315). A bump (240, 340) is positioned overlying the opening (120, 220, 320) and substantially overlying the passivation layer (130, 230, 330). The bump (240, 340) is formed to be in electrical contact with the contact pad (315). The bump (240, 340) is arranged to couple the first and second electrical components (110, 180; 410, 480) during the flip-chip coupling process.

The present system relates to an interconnection method and device that uses a flip-chip type of electrical interconnection with a relatively small passivation layer opening.

Current state of the art integrated circuits (ICs) are continuously shrinking in size and increasing in complexity. As density of components increases, the system of electrically coupling components has become critical in that the physical interconnections occupy a signification portion of available surface area reducing the ability to position electrical circuitry within this area.

An electrical interconnection technology is known wherein one portion of the interconnection is formed by a contact bump and another portion of the interconnection is formed by a contact pad or surface. During the manufacturing process, the bump and pad are brought into contact with each other to form the electrical interconnection. U.S. Pat. No. 6,015,652 incorporated herein by reference as if set out in entirety discloses a type of such an interconnection system termed “flip-chip bonding” for ICs mounted on a substrate. This typical interconnection system alleviates some of the problems associated with other electrical interconnection systems, yet still occupies much of available surface area that might otherwise be utilized for electronic components. This problem is exacerbated further when the electrical interconnection is made directly to an integrated circuit, such as an Application-Specific Integrated Circuit (ASIC).

PCT Patent Application WO 2004/052209 incorporated herein by reference as if set out in entirety, discloses a system of electrically coupling an ASIC to a plurality of acoustic elements for the purposes of forming a miniaturized transducer array. In the shown system, the bump is electrically coupled to one of the acoustic element or ASIC and the pad is electrically coupled to the other of the acoustic element or ASIC. This system realizes a small electrical package that for example, may be formed to create an ultrasonic transducer that may be utilized for transesophageal, laparoscopic and intra-cardiac examination. Nonetheless, since these products assume a pitch match of the cell circuitry directly under the acoustic element, it is desirable to reduce the pitch further. The current mixed-signal ASIC processes and voltages that are needed for proper operation still limit further reduction of the acoustic element and control circuitry. For example, for a flip-chip interconnection system using stud-shaped bumps positioned on a 185 um pitch array, approximately 40% of the area of the ASIC is not usable for circuitry due to these bumps.

In known and practiced processes, such as stud bumping and electroplating bumps, the bumps are substantially positioned on the pads through the passivation layer opening, typically with little or no overlap of the bump on the passivation layer. In other words, in prior systems, the size of the footprint of the bump is very close to the size of the contact pad. This large interconnection between the stud and contact pad together with constraints in electrically coupling the stub and contact pad in prior systems is what predominantly results in the unusable portions of the ASIC.

It is an object of the present system to overcome disadvantages and/or make improvements in the prior art. It is an object of the present system to produce a tall bump while minimizing consumption of the ASIC real-estate.

In accordance with the present system, a flip-chip electrical coupling is formed between first and second electrical components. The coupling includes a bump and a contact pad. The first electrical component includes a contact pad electrically coupled to the first electrical component and a passivation layer overlying the first electrical component and the contact pad. The passivation layer is arranged having an opening positioned over the contact pad. A bump is positioned overlying the opening and substantially overlying the passivation layer. The bump is formed to be in electrical contact with the contact pad. The bump is arranged to couple the first and second electrical components during the flip-chip coupling process. In one embodiment, a ratio of a surface area of the opening to a surface area of the passivation layer overlaid by the bump is in the range of 5% to 85% or 5% to 30%. In one embodiment, the first electrical component includes an under bump metallization layer configured to electrically couple the contact pad to the bump. The bump may be arranged as a plurality of layers that are deposited during an electroplating process. In one embodiment, the first electrical component is an ASIC and/or the second electrical component is a transducer array.

The present system also includes a method for forming a flip-chip electrical coupling between the first and second electrical components, wherein the first electrical component is covered by a passivation layer. The method includes the acts of forming an opening in the passivation layer over a contact pad of the first electrical component, depositing a bump overlying the opening and substantially overlying the passivation layer, and coupling electrically the bump to the contact pad.

Prior to the act of depositing the bump, the method may include the act of depositing an under bump metallization layer in electrical contact with the contact pad. In this embodiment, the act of coupling electrically the bump to the contact pad includes the act of coupling electrically the bump to the under bump metallization layer. Portions of the under bump metallization layer that is not overlaid by the bump may be removed. The under bump metallization layer may be sputter deposited. The bump may be deposited by electroplating a plurality of layers of the bump until the bump height is in a range of 70-100 um.

The second electrical component may be flip-chip coupling to the bump. Following the act of flip-chip coupling, the second electrical component may be diced to form a plurality of elements from the second electrical component.

In the same or another embodiment, the first electrical component may be an acoustic element and/or the second electrical component may be an ASIC. The coupling may be one of a plurality of electrical couplings present in a pitch array of less than 150 um.

The invention is explained in further detail, and by way of example, with reference to the accompanying drawings wherein:

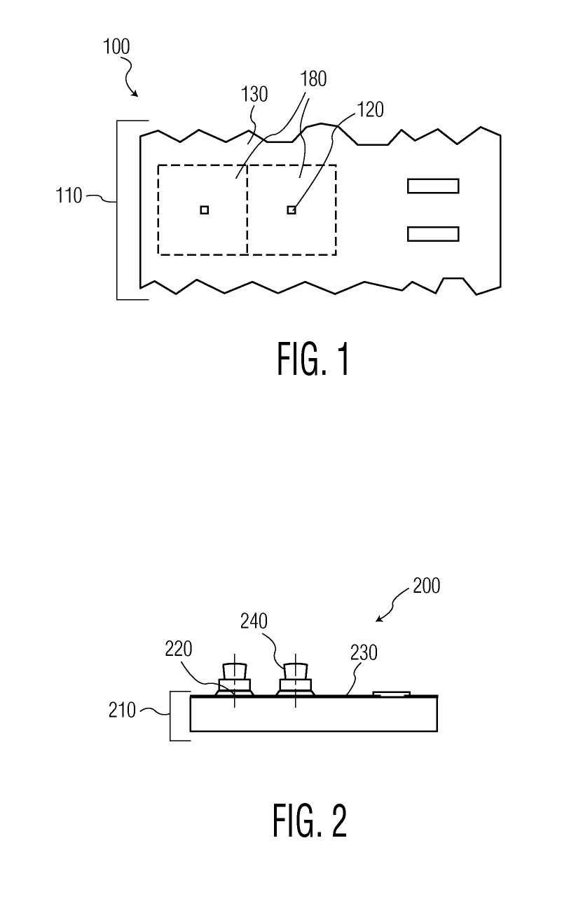

FIG. 1 shows an illustrative overhead view of an ASIC prepared for a flip-chip interconnection in accordance with an embodiment of the present system;

FIG. 2 shows an illustrative cross-section of a flip-chip interconnection in accordance with an embodiment of the present system;

FIG. 3 shows a detailed cross-sectional area of the illustrative flip-chip interconnection system shown in FIG. 2 in accordance with an embodiment of the present system; and

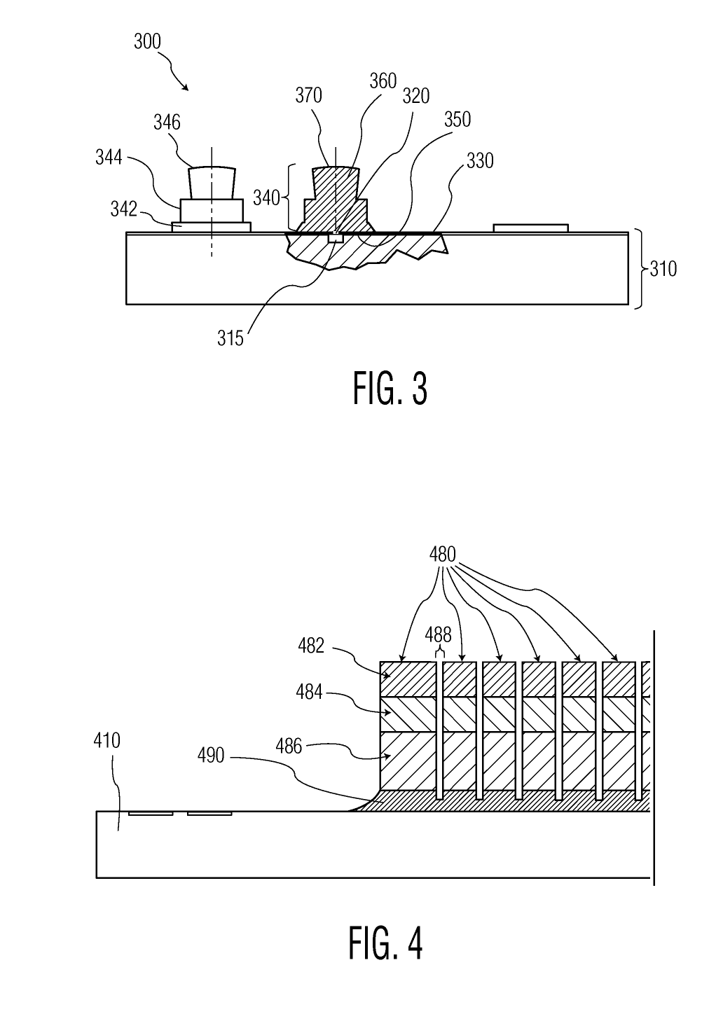

FIG. 4 shows an illustrative element, such as a plate of acoustic elements that may be coupled to an electrical component in accordance with the present system.

The following are descriptions of illustrative embodiments that when taken in conjunction with the drawings will demonstrate the above noted features and advantages, as well as further ones. In the following description, for purposes of explanation rather than limitation, specific details are set forth such as architecture, interfaces, techniques, etc., for illustration. However, it will be apparent to those of ordinary skill in the art that other embodiments that depart from these details would still be understood to be within the scope of the appended claims. Moreover, for the purpose of clarity, detailed descriptions of well-known devices, circuits, and methods are omitted so as not to obscure the description of the present system. In addition, it should be expressly understood that the drawings are included for illustrative purposes and do not represent the scope of the present system. In the accompanying drawings and description, like reference numbers are utilized to designate similar elements.

FIG. 1 shows an illustrative overhead view 100 of an integrated circuit, such as an ASIC 110, prepared for a flip-chip interconnection in accordance with an embodiment of the present system. The ASIC 110 is covered by a passivation layer 130 that insulates and protects an underlying layer of the ASIC 110. The passivation layer 130 has an opening 120 that is small compared to prior systems. The overhead view 100 includes an indication of two overlying elements, such as acoustic elements 180, which are coupled to the ASIC 110 via the opening 120 and a bump (not depicted in FIG. 1) in accordance with the present system.

FIG. 2 shows an illustrative cross-section of a flip-chip interconnection system 200 in accordance with an embodiment of the present system. In this embodiment, a high aspect bump 240 is shown in a form of a stud bump that during fabrication is electrically coupled to a de-matching layer surface of an acoustic element (not shown). Illustratively, the bump 240 may be in any form including a ball, and/or stud. The acoustic element may be of a type for generating ultrasonic energy emissions as may be useful in an ultrasonic transducer application. As indicated above, the bump 240 illustratively is a high aspect bump to account for tolerances in the fabrication and preparation of the element or elements that are being electrically coupled to an ASIC 210.

FIG. 4 shows an illustrative element, such as a plate of acoustic elements 480 that may be coupled to an electrical component, such as an ASIC 410, in accordance with the present system. Illustratively, for applications wherein the ASIC 410 is flip-chip coupled to an acoustic array, there is a need for a relatively large, for example 70-100 um, bump height. These types of two-dimensional arrays, such as shown in FIG. 4, typically have very many (e.g., 2,000-10,000) acoustic elements 480 (transducer material) positioned directly above and flip-chip bonded through the bump to the ASIC 410. The bonding of the bumps to the acoustic array may be brought about by any suitable bonding process including utilizing a conductive adhesive applied to either of the bumps or a contacting surface of the acoustic array, ultrasonic stub bump bonding, etc.

The ASIC 410 is typically dimensioned physically larger than the plate of acoustic material. After flip-chip bonding of the plate to the ASIC 410, an underfill 490 may be applied to stabilize the plate with regard to the ASIC 410, collectively termed an assembly. The underfill helps to protect the bumps from environmental conditions, provides additional mechanical strength to the assembly, may act as a heat sink to help dissipate heat away from active components of the ASIC, and may help compensate for any thermal expansion differences between the acoustic components 480 and the ASIC 410.

The plate is than cut (e.g., see cut 488), for example with a dicing saw (e.g., diamond particle saw), to separate the plate into the individual acoustic elements 480 that during the flip-chip bonding process and thereafter, are positioned above each bump (bumps not shown in FIG. 4 for clarity). It should be readily appreciated that the acoustic elements 480 may be of any type and configuration including a configuration that facilitates 3-dimensional (3-D) imaging such as may be utilized for a 3-D ultrasonic imaging application and/or matrix transducer configuration.

The difficulty of electrically coupling the ASIC 410 to the acoustic elements 480 is compounded by a required dicing tolerance. The cuts 488 separating the individual acoustic elements 480 have to be deep enough to separate the plate into the individual acoustic elements 480. However, cutting too deep will create a risk of damaging the underlying ASIC 410 (e.g., the cut may pass through the ASIC surface area). There are several components that make the requirements for a larger dicing depth tolerance that together result in a requirement for a large bump height (e.g., 70-100 um). First, there are variations in the thickness of the plate. Typically the plate is a laminate of three or more materials, namely a de-matching layer 486 (e.g., tungsten carbide), a piezoelectric crystal 484 which is the transponder, and a matching layer 482 (e.g., graphite). The three laminating materials, for example, each with different physical properties results in plates that are not perfectly flat.

In addition, making so many cuts (e.g., thousands) results in saw blade wear of the dicing saw. Accordingly, even for a given depth cut, the last cuts are of different depth that the initial cuts due to the blade wear so the cuts typically are made to account for the shallower, later cuts. Further, a structure that consists of many parts previously joined (e.g., laminated) together in several separate processes has a problem of accumulating tolerances. For example, a tolerance in a thickness of the layers plus a tolerance in a flatness of the layers plus a tolerance in a bond thickness results in a large accumulated tolerance.

All the components listed above adds up to a need for a relatively large (e.g., 70-100 um) gap between the plate and ASIC. This requirement for a large gap translates to a corresponding large bump height.

FIG. 3 shows a detailed cross-sectional area of the illustrative flip-chip interconnection system 300 in accordance with an embodiment of the present system. The flip-chip interconnection system 300 includes an electrical component, such as an ASIC 310 and a bump 340. The ASIC 310 has contact pads 315, such as aluminum pads that are covered by a passivation layer 330 (e.g., layer of silicon nitrite). In accordance with an embodiment of the present system, the pads 315 are formed small compared to prior systems, such as 5-30 um in diameter. An opening 320 through the passivation layer 330 is made above and through to the contact pads 315 utilizing a suitable process, such as by an electro-lithography etching process, plasma back sputter, etc. During the removal of the passivation layer or during a subsequent process, oxides, such as aluminum oxides, are removed from the contact pads 315 to ensure good electrical contact of a next formed, under bump metallization layer (UBM) 350. The UBM 350 may be formed in multiple layers having different metallurgical qualities, such as titanium with gold plating on top. The UBM 350 typically overlaps the passivation layer 330 to ensure good electrically conductive adhesion (e.g., plating) to the contact pads 315. The UBM 350 also protects the ASIC (e.g., seal the contact pad) from environmental conditions, such as oxidation and chemical processes that may be utilized in subsequent steps. The UBM 350 may be formed by any suitable process, such as a sputtering deposition over a top surface of the ASIC 310, electrolysis plating, photo-deposition, etc.

The bump 340 is then formed over the opening 320 through the passivation layer 330. The bump 340 substantially overlies a portion of the passivation layer 330. Typical prior art bumps only overlie a very small portion of the passivation layer (e.g., <3%) since as discussed above, the bump is typically similarly sized as the underlying contact pad. In prior systems, the sizing of the bump to the contact pad is a way of reducing wasted real estate of the ASIC. In the present system, the substantial overlying of the bump 340 over the passivation layer 330 achieves even greater improvements in the use of the ASIC 310 real estate. For example, the present system of interconnection may be suitably applied in fine-pitched arrays of 150 um and less. As utilized herein, the term substantial overlying of the bump over the passivation layer is intended to mean that between ten and ninety-five percent (10%<overlie<95%) of the footprint of the bump overlies the passivation layer. In one embodiment, more than fifty percent (e.g., 70%-95%) of the footprint of the bump may overlie the passivation layer, yet the size of the contact pad is maintained relatively small which results in a potentially improved circuit density.

The bump 340 may be fabricated using any fabrication process, such as plating, machining, forming, wire-bonding, electro-lithography, etc. In one embodiment, the bump 340 is formed during an electroplating process. The electroplating process consists of creating a plating mask that defines the area to be plated on the surface of the ASIC 310. This plating mask also defines the footprint of the bump 340.

In a particular embodiment, it may be desirable to form the bump utilizing multiple, separate plating processes to enable a desired feature resolution and bump height. Furthermore the plating conditions (e.g., chemistry, temperature, and time) may cause the plating mask to deteriorate should too deep a plating mask be utilized. A multi-step plating process may result in a pyramid shape as illustratively depicted in FIG. 3 for the bump 340. In this embodiment, a different mask may be utilized for each plating step. A size of each of successive plated levels 342, 344, 346 of the bump 340 may be smaller to enable positioning of the plating masks. A same size mask may result in problems in properly positioning the mask which would result in an uncontrolled shape of the bump. The bump 340 may be formed of any desired metallurgy, such as a nickel and/or nickel composition 360.

The completed bump 340, for example, after two one more electroplating processes, may be in a range of 50-120 um high, such as 100 um high, and have a footprint in a range of 50-80 um, such as a footprint of 60 um. After the bump 340 is completed, the UBM 350, other than portions positioned under the bump 340, may be removed by any suitable process, such as by a chemical etching process. The bump 340 may thereafter by plated by any suitable process, such as by a gold electroless (without an electrode) plating process resulting in a plating layer 370 (e.g., gold) over the bump 340.

Advantageously, the interconnection system in accordance with the present system consumes less of the ASIC area for contact pads and may result in more real estate of the ASIC available for circuitry (e.g., added features) or may enable smaller pitch designs than present systems.

Of course, it is to be appreciated that any one of the above embodiments or processes may be combined with one or with one or more other embodiments or processes to provide even further improvements in accordance with the present system.

Finally, the above-discussion is intended to be merely illustrative of the present system and should not be construed as limiting the appended claims to any particular embodiment or group of embodiments. Thus, while the present system has been described in particular detail with reference to specific exemplary embodiments thereof (e.g., ASIC, acoustic elements, etc.), it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

In interpreting the appended claims, it should be understood that:

a) the word “comprising” does not exclude the presence of other elements or acts than those listed in a given claim;

b) the word “a” or “an” preceding an element does not exclude the presence of a plurality of such elements;

c) any reference signs in the claims do not limit their scope;

d) several “means” may be represented by the same item or hardware or software implemented structure or function;

e) any of the disclosed elements may be comprised of hardware portions (e.g., including discrete and integrated electronic circuitry), software portions (e.g., computer programming), and any combination thereof;

f) hardware portions may be comprised of one or both of analog and digital portions;

g) any of the disclosed devices or portions thereof may be combined together or separated into further portions unless specifically stated otherwise; and

h) no specific sequence of acts or steps is intended to be required unless specifically indicated.

1. A flip-chip electrical coupling (100, 200, 300) between first and second electrical components (110, 180; 410, 480), the coupling (100, 200, 300) comprising:
the first electrical component (110, 210, 310, 410) comprising:
a contact pad (315) electrically coupled to the first electrical component (110, 210, 310, 410); and
a passivation layer (130, 230, 330) overlying the first electrical component (110, 210, 310, 410) and the contact pad (315), wherein the passivation layer (130, 230, 330) is configured to have an opening (120, 220, 320) positioned over the contact pad (315); and
a bump (240, 340) overlying the opening (120, 220, 320) and substantially overlying the passivation layer (130, 230, 330), the bump (240, 340) being in electrical contact with the contact pad (315) and configured for coupling the first and second electrical components (110, 180; 410, 480) during the flip-chip coupling.

2. The coupling (100, 200, 300) of claim 1, wherein a ratio of a surface area of the opening (120, 220, 320) to a surface area of the passivation layer (130, 230, 330) overlaid by the bump (240, 340) is in the range of 5% to 85%.

3. The coupling (100, 200, 300) of claim 1, wherein a ratio of a surface area of the opening (120, 220, 320) to a surface area of the passivation layer (130, 230, 330) overlaid by the bump (240, 340) is in the range of 5% to 30%.

4. The coupling (100, 200, 300) of claim 1, wherein the bump (240, 340) overlies a larger surface area of the passivation layer (130, 230, 330) than the opening (120, 220, 320).

5. The coupling (100, 200, 300) of claim 1, wherein the first electrical component (110, 210, 310, 410) comprises an under bump metallization layer (350) configured to electrically couple the contact pad (315) to the bump (240, 340).

6. The coupling (100, 200, 300) of claim 1, wherein the bump (240, 340) is configured as a plurality of layers (342, 344, 346) that are deposited during an electroplating process.

7. The coupling (100, 200, 300) of claim 1, wherein the first electric component (110, 210, 310, 410) is an ASIC.

8. The coupling (100, 200, 300) of claim 1, wherein the second electrical component (180, 480) is a transducer.

9. A method for forming a flip-chip electrical coupling (100, 200, 300) between first and second electrical components(110, 180; 410, 480), wherein the first electrical component (110, 210, 310, 410) is covered by a passivation layer (130, 230, 330), the method comprising the acts of:
forming an opening (120, 220, 320) in the passivation layer (130, 230, 330) over a contact pad (315) of the first electrical component (110, 210, 310, 410);
depositing a bump (240, 340) overlying the opening (120, 220, 320) and substantially overlying the passivation layer (130, 230, 330); and
coupling electrically the bump (240, 340) to the contact pad (315).

10. The method of claim 9, wherein prior to the act of depositing the bump (240, 340), the method comprising the act of depositing an under bump metallization layer (350) in electrical contact with the contact pad (315), and wherein the act of coupling electrically the bump (240, 340) to the contact pad (315) comprises the act of coupling electrically the bump (240, 340) to the under bump metallization layer (350).

11. The method of claim 10, comprising the act of removing portions of the under bump metallization layer (315) that are not overlaid by the bump (240, 340).

12. The method of clam 10, wherein the act of depositing the under bump metallization layer (315) comprises the act of sputter depositing the under bump metallization layer (315).

13. The method of claim 9, wherein the act of depositing the bump (240, 340) comprises the act of electroplating a plurality of layers (342, 344, 346) of the bump (240, 340) until the bump height is in a range of 70-100 um.

14. The method of claim 9, wherein the act of depositing the bump (240, 340) comprises the act of depositing the bump (240, 340) to overlay a ratio of the opening (120, 220, 320) to a surface area of the passivation layer (130, 230, 330) in the range of 5% to 30%.

15. The method of claim 9, comprising the act of flip-chip coupling the bump (240, 340) to the second electrical component (180, 480).

16. The method of claim 15, comprising the act of dicing the second electrical component (180, 480) following the act of flip-chip coupling.

17. The method of claim 15, wherein the second electrical component (180, 480) is an acoustic element.

18. The method of claim 15, wherein the act of flip-chip coupling is one of a plurality of electrical couplings formed within a pitch array of less than 150 um.

19. The method of claim 18, comprising the act of dicing the second electrical component (180, 480) following the act of flip-chip coupling to form a plurality of acoustic elements (480) from the second electrical component (180, 480).

20. The method of claim 15, wherein the first electrical component (110, 210, 310, 410) is an ASIC and the second electrical component (180, 480) is an acoustic element.
